(19) United States
(12) Patent Application Publication
(10) Pub. No.: US 2019/0052063 A1
(43) Pub. Date: Feb. 14, 2019

(54) Tunable Laser Array Integrated with Separately Tuned Wavelength-Division Multiplexer

(71) Applicant: HUAWEI TECHNOLOGIES CO., LTD., Shenzhen (CN)

(72) Inventor: Valery Tolstikhin, Ottawa (CA)

(21) Appl. No.: 15/676,612

(22) Filed: Aug. 14, 2017

(51) Int. Cl. H01S 5/40; H01S 5/12; H01S 5/068; H01S 5/024; H01S 5/026

(52) U.S. Cl. CPC H01S 5/4087; H01S 5/12; H01S 5/026; H01S 5/02415; H01S 5/06808; H01S 5/06804

(57) ABSTRACT

A tunable laser array photonic integrated circuit (PIC) is disclosed. The PIC may include an epitaxial structure on a substrate and multiple laser diodes in the epitaxial structure. Each laser diode may operate in a range of wavelengths and may be continuously tunable within the range based at least in part on a temperature of the substrate and a bias current applied to the laser diode. A wavelength-division multiplexer (WDM), configured to receive light from each laser diode, is provided in the epitaxial structure of the PIC. A passband center wavelength of the WDM is selectively temperature tunable by a local heater coupled to the WDM.

### BACKGROUND

A widely tunable laser source may be used instead of several fixed light sources in a wavelength division multiplexing (DWDM) system. By having a single device that can emit light at various wavelengths, it may be possible to reduce a component count. Therefore, a reduction in part inventory can be achieved.

Optical assemblies often require a precise alignment, which can be a major impediment to volume-scale production of such assemblies. It may be beneficial for components to be implemented using a photonic integrated circuit (PIC), which achieves alignment by way of lithography. However, implementation of a widely tunable laser source in a PIC remains a challenge.

### SUMMARY

In various arrangements, a photonic integrated circuit (PIC) is presented. The PIC may include a substrate, an epitaxial structure upon the substrate, and a plurality of laser diodes in the epitaxial structure. A wavelength of each laser diode of the plurality of laser diodes may be tunable within a tuning range based at least in part on a temperature and a bias current of each laser diode. The PIC may further include a wavelength-division multiplexer (WDM) in the epitaxial structure. The WDM may be configured to receive light from each laser diode of the plurality of laser diodes, wherein passband center wavelengths of the WDM are continuously tunable based at least in part on a temperature of the WDM. The PIC may further include a heater disposed and configured to selectively heat the WDM.

Embodiments of such a PIC may include one or more of the following features: The plurality of laser diodes and the WDM may be disposed and configured such that laser emission wavelengths and the WDM passband center wavelengths are controllable independently on one another. The WDM may include an Echelle grating (EG) having a slab waveguide region. Each laser diode of the plurality of laser diodes may be a distributed feedback, directly modulated laser (DFB-DML) of a plurality of DFB-DMLs. The WDM may include an Echelle grating (EG) having a slab waveguide region. The heater may include a conductive layer adjacent and thermally coupled to the slab waveguide region of the EG. The PIC may include a dielectric layer on the epitaxial structure, wherein the heater comprises a metal resistive heater disposed on the dielectric layer adjacent and thermally coupled to the slab waveguide region of the EG. Each DFB-DML of the plurality of DFB-DMLs may have a distributed feedback (DFB) grating having a pitch. The DFB grating pitches may differ from one another, whereby each DFB-DML of the plurality of DFB-DMLs has a different tuning range. A temperature of each individual DFB-DML of the plurality of DFB-DMLs may be at least partially controlled based on a bias current supplied to the individual DFB-DML. The PIC may include a semiconductor optical amplifier (SOA) in the epitaxial structure, wherein the SOA receives and amplifies output light from the WDM. The plurality of laser diodes may include at least ten laser diodes. The PIC may include a plurality of photodiodes on the substrate. Each photodiode of the plurality of photodiodes may be optically coupled to a different laser diode of the plurality of laser diodes. A photodiode of the plurality of photodiodes may be optically coupled to the WDM. The substrate may be an InP substrate. The substrate may be configured to be cooled by a thermoelectric cooler.

In some embodiments, a tunable light source is presented. The tunable light source may include a photonic integrated circuit (PIC), comprising: a substrate; an epitaxial structure on the substrate; and a plurality of laser diodes in the epitaxial structure. Each laser diode may be tunable within a tuning range based at least in part on a temperature and a bias current of each laser diode. The PIC may further include a wavelength-division multiplexer (WDM) in the epitaxial structure, wherein the WDM is configured to receive light from each laser diode of the plurality of laser diodes, wherein passband center wavelengths of the WDM are continuously tunable based at least in part on a temperature of the WDM. A heater may be disposed and configured to selectively heat the WDM. A thermally-conductive substrate may be in thermal contact with the PIC. A thermoelectric cooler may be in thermal contact with the thermally-conductive substrate.

Embodiments of such a tunable light source may include one or more of the following features: The WDM may include an Echelle grating (EG) having a slab waveguide region. The heater may include a conductive layer adjacent the slab waveguide region of the EG. The WDM may include an Echelle grating (EG) having a slab waveguide region. The tunable light source may further include a dielectric layer on the epitaxial structure, wherein the heater comprises a metal resistive heater disposed on the dielectric layer adjacent the slab waveguide region of the EG. The plurality of laser diodes may be a plurality of distributed feedback directly-modulated lasers (DFB-DMLs). The system may further include a semiconductor optical amplifier (SOA) defined within the epitaxial structure that receives and amplifies light output from the WDM.

In some embodiments, a method for using a tunable laser array photonic integrated circuit (PIC) is presented. The PIC may include a substrate and an epitaxial structure on the substrate, the epitaxial structure may include a plurality of laser diodes and a wavelength-division multiplexer (WDM) optically coupled to the plurality of laser diodes using optical waveguides. The method may include controlling a temperature of the PIC using a thermoelectric cooler. The method may include adjusting a wavelength of a first laser diode of the plurality of laser diodes to match a target wavelength by altering a bias current supplied to the first laser diode. The method may include selectively applying heat to the WDM to adjust a passband center wavelength of the WDM to match the target wavelength.

Embodiments of such a method may include one or more of the following features: The WDM may include an Echelle grating comprising a slab waveguide, and wherein the heat is selectively applied to the slab waveguide. The method may include selecting the first laser diode such that the target wavelength is within a tunable wavelength range of the first laser diode.

### BRIEF DESCRIPTION OF THE DRAWINGS

FIG. 1 is a block diagram of an embodiment of a tunable laser array photonic integrated circuit (PIC).

FIG. 2 is a block diagram of a tunable laser array PIC that includes analog distributed-feedback (DFB), directly-modulated lasers (DMLs) and an Echelle grating (EG) wavelength-division multiplexer (WDM).

FIG. 3 is a block diagram of a system comprising a tunable laser array PIC.

FIGS. 4A and 4B are plane views of an Echelle grating structure including heaters incorporated therein.

FIG. 5 is an exemplary spectral chart of a dense wavelength-division multiplexing (DWDM) wavelength plan.

FIG. 6 is a flow chart of a method for emitting light at a desired wavelength using a PIC as described herein.

### DETAILED DESCRIPTION

Analog radio over fiber (ARoF), radio over fiber (RoF), and RF over fiber (RFoF) systems (collectively referred to herein as RoF) utilize light modulation by an RF signal and transmitting the modulated light via an optical fiber. Transmitting an RF signal in such a manner can provide various benefits, including reduced sensitivity to noise and electromagnetic interference compared to electrical signal transmission. Further, RoF implementations do not need as much amplification to traverse distances in optical fiber, since optical signals tend to propagate through optical fiber with less attenuation than electrical signals through metal cables or electromagnetic signals through air.

Laser diodes, such as analog distributed-feedback directly-modulated lasers (DFB-DMLs) are wideband, narrow linewidth, and low-noise light sources that have good modulation linearity at high optical powers. Thus, DFB-DMLs may be desirable for RoF applications. “Light” as used within this document refers generally to electromagnetic radiation (EMR), both visible and invisible, including infrared light, visible light, and ultraviolet light.

A monolithic photonic integrated circuit (PIC) contains discrete optical components epitaxially grown on a substrate. The optical components do not require an active optical alignment because the alignment is achieved via lithography at the time of manufacture, as opposed to discrete optical components needing to be individually aligned in free space. DFB-DMLs may be incorporated as part of a PIC and may serve as a laser source for RoF applications. Further, wavelength tunability of output light may be desired. DFB-DMLs may have their output wavelength, and a corresponding wavelength, tunable within a certain range.

To provide tunability, DFB-DMLs can be equipped with a pair of gratings forming an optical cavity. In this configuration, discrete wavelength tunability of output light is achieved by matching resonance wavelengths of the pair of gratings each forming a sub-cavity, via the Vernier effect. Narrow-range tuning can then be achieved by altering the properties of the complex cavity that includes the gratings' sub-cavities. Such configurations, however, are rather complex, which results in optical power, noise, and linearity being traded off for wavelength tunability.

Another approach to wavelength tunability of a laser source is to provide tunable laser arrays (TLAs) that use laser diodes on a monolithic PIC. In this approach, each laser of the TLA is coupled to a wavelength-insensitive wideband beam combiner to combine the outputs of each discrete laser diode. Such wideband beam combiners typically introduce a large amount of optical loss. The loss introduced by such a wideband beam combiner may be determined according to equation 1:

$$L = 10 log \frac{1}{M} \qquad Eq . 1$$

M represents the number of laser diodes having their outputs combined and L (in dB) represents the power loss by the wideband beam combiner from each laser diode, ignoring insertion loss. Therefore, if, for example, ten laser diodes are present, the wideband beam combiner would decrease the output power from any individual laser diode by at least 90%. Such a large power loss is undesirable, and is too high for most RoF applications.

A wavelength-division multiplexing (WDM) beam combiner may be used instead of the wideband beam combiner. Passband center wavelengths of the WDM beam combiner may need to be tuned to the emitting wavelengths of the laser diodes in the array. The use of WDM beam combiner, while requiring tuning of the passband center wavelengths, significantly decreases the coupling loss as compared to a wideband beam combiner. Therefore, WDM beam combiner may be preferable for RoF applications, as well as for other applications requiring efficient combining of many laser sources at different wavelengths.

Various embodiments of a monolithic PIC with multiple individually tunable laser diodes are presented herein. Each of the laser diodes can be made temperature tunable over a wavelength range wide enough for individual wavelength ranges of the laser diodes to overlap. A temperature tunable WDM may then be used to combine the light emitted by individual laser diodes. Such a configuration allows the wavelength of output light to be continuously tunable within a wide range, significantly exceeding a range of tunability of individual laser didoes. Further, a temperature-tunable Echelle grating WDM (EG-WDM) may be used to combine light emitted by individual laser diodes. The EG-WDM and one or more of the laser diodes may be kept at different temperatures to achieve a desired matching of a passband center wavelength of the EG-WDM to a wavelength of light emitted by an active laser diode. An EG-WDM combined with a laser array may be simpler to manufacture than a complex cavity based, widely tunable laser diode.

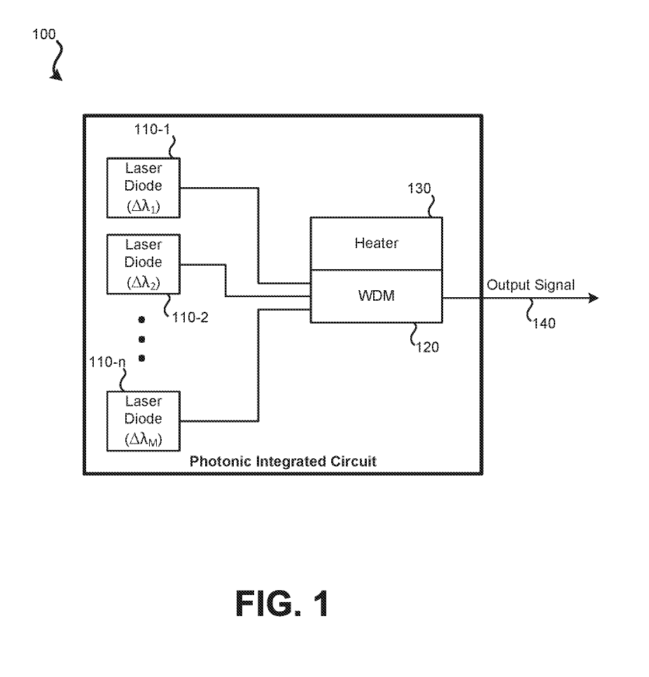

FIG. 1 illustrates an embodiment of a tunable laser array PIC 100. Various components of PIC 100 may be epitaxially grown on the substrate. PIC 100 may include: plurality of laser diodes 110; WDM 120, and heater 130. Each of these components may be part of a monolithic PIC. That is, each of these components may be epitaxially formed on a same substrate and defined by lithography. PIC 100 may be formed by III-V semiconductor layers being epitaxially grown on a substrate layer of indium phosphide (InP). It should be understood that other embodiments may use another substrate, or another material system.

As illustrated, PIC 100 includes three laser diodes 110 (110-1, 110-2, and 110-n). It should be understood that the number of laser diodes is merely exemplary, fewer or greater numbers of laser diodes may be present. For instance, in an embodiment in which 32 or 64 wavelengths corresponding to an optical frequency grid are to be covered, some number of laser diodes that can be less than 32 or 64, respectively, may be used, such as ten. For example, 10 laser diodes 110 may be used to cover 32 channels of a 100 GHz spaced optical frequency grid or 64 channels of a 50 GHz spaced optical frequency grid (which may be used for DWDM frequency plans in C-band). Therefore, depending on factors including wavelength channel spacing, the number of laser diodes 110 may be, for example, less than 20% the number of channels which PIC 100 can emit. It should be understood that the number of laser diodes 110 can vary by embodiment, and that in certain embodiments, 10, 20, 30, or some other number of laser diodes 110, fewer or greater, may be possible. In other embodiments, it may be desirable to match the number of laser diodes 110 to the number of the wavelength channels that PIC 100 can output.

Laser diodes 110 of PIC 100 may each be distributed feedback, directly modulated lasers (DFB-DMLs). The distributed feedback of the laser diodes may allow for wavelength tuning within a wavelength range of tunability, while the direct modulation may allow for high power output. Further, DFB-DMLs are integrated into PIC 100. Other types of laser diodes, that can achieve wavelength tunability at high output power, may be incorporated into a PIC. Each of laser diodes 110 of PIC 100 may be individually continuously tunable over a wavelength range. Each of laser diodes 110 may be tunable over a different but overlapping continuously tunable wavelength ranges (as indicated by different continuously tunable wavelength ranges Δλ₁, Δλ₂, and Δλ_{M}). These individual laser diode wavelength ranges may at least partially overlap with each other such that a larger continuous range of wavelengths exists over which at least one laser diode of laser diodes 110 is tunable. The output wavelength by each laser diode may be at least partially based on temperature of the laser diode 110. The temperature of the surface on which each of laser diodes 110 is mounted affects the temperature of the laser diode. The temperature of each of laser diodes 110 is further affected by the laser diode's bias current, because of associated self-heating, bandgap shrinkage, plasma screening, and band-filling effects on refractive index of laser's active region. The bias current provided to a laser diode also defines the output optical power of the laser diode. By adjusting both the PIC substrate temperature and the laser's bias current, the emission wavelength and the output power of the laser diode can be controlled simultaneously.

Each of laser diodes 110 outputs light to the WDM 120, which is temperature tunable independently of laser diodes 110. The WDM 120 is integrated with the array of laser diodes 110 as part of a same monolithic PIC. Temperature-tunable WDM 120 has its passband center wavelengths temperature tuned over a certain range, sufficient for adjustment within the ranges of laser diodes array. When a WDM passband center wavelength is tuned to a laser diode emission wavelength, coupling loss may be minimized. In order to control the passband center wavelengths of WDM 120, the WDM 120 may be in close proximity with heater 130. Heater 130 may be connected with a separate electric controller that controls an amount of heat generated by heater 130. The electronic controller may be located off of PIC 100. Heater 130 may create heat that is primarily absorbed by the WDM 120, with little of the heat generated by heater 130 being transferred to laser diodes 110. As such, heater 130 primarily heats only thermally-adjustable WDM.

While laser diodes 110 and WDM 120 may have their temperatures individually affected by applied bias current and heater 130, respectively, PIC 100 may be coupled to a temperature tuning element, such as a thermoelectric cooler (TEC). PIC 100 may be in physical contact with a separate thermally conductive substrate, such as a thermally conductive piece of metal that transfers heat to the TEC. The TEC may control the temperature of PIC 100 at a constant value, while the bias current of laser diodes 110 is used to change the laser diode emission wavelength, at least in part by locally raising the temperature of the laser diode. Heater 130 is used to selectively, that is, independently of other areas of PIC, control the temperature of WDM 120.

Output signal 140 represents the signal output by PIC 100. In some embodiments, the analog signal being carried by output signal 140 is modulated with the carrier signal at the appropriate laser diode of laser diodes 110. Such an arrangement may be preferable for RoF applications. In other embodiments, Output signal 140 may be modulated with another signal, such as an RF signal, after output from PIC 100.

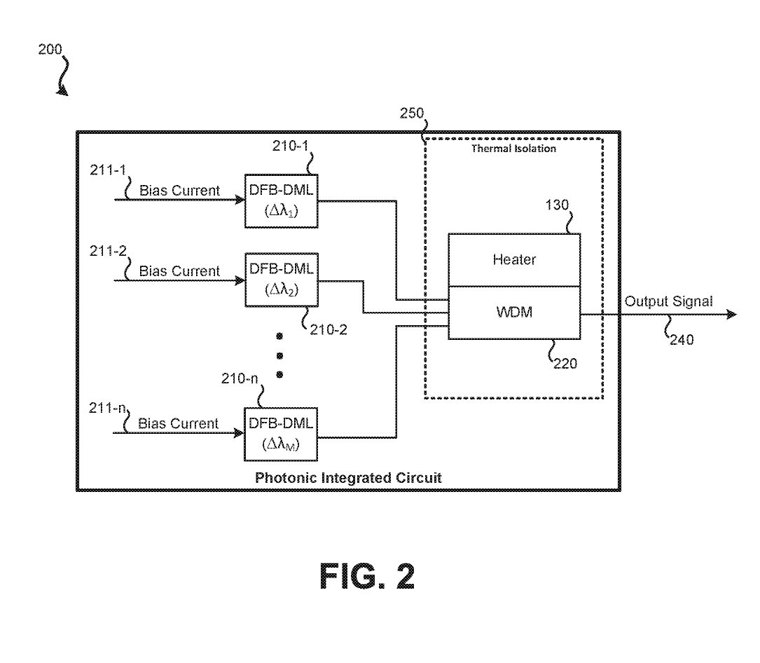

FIG. 2 illustrates an embodiment of a tunable laser array PIC 200 that includes DFB-DMLs and an EG WDM. Embodiments of PIC 200 can emit light at wavelengths corresponding to a target optical frequency grid, such as the International Telecommunication Union (ITU) grid, which define standardized channels used for communication over optical fiber. Since different equipment that functions independently of each other will be used for transmission and reception, operating on standardized optical frequency channels which may be evenly spaced (by δf), may allow the transmitting and receiving equipment to properly communicate. For evenly spaced channels, if N channels are present, Equation 2 can define the frequency spacing of the channels:

fᵢ₊₁−fᵢ=δf for 1≤i≤N Eq. 2

PIC 200 represents a more detailed embodiment of PIC 100 of FIG. 1. In PIC 200, the laser diodes are specifically noted as DFB-DMLs. The wavelength emitted by each DFB-DML is determined by the Bragg resonance conditions in the DFB-DML's waveguide coupled to the DFB grating, which, in turn, are defined by the waveguide mode's effective refractive index n_{DFB} and grating period Λ as:

$${λ}_{DFB} = \frac{2 Λ {n}_{DFB} ( {λ}_{DFB} )}{m} \qquad Eq . 3$$

In equation 3, m is the Bragg resonance order. If all DFB-DML waveguides share the same epitaxial structure and have the same vertical cross-section, the intended emission wavelength variance within the array of DFB-DMLs under the same operating conditions is due to the variation of the grating pitches. Variation of operation conditions, such as the substrate temperature and the bias current, can change the lasing mode's effective index and, hence, the emission wavelength. This kind of variation can be intentional and controlled by external means that makes it suitable for both the compensation of the unintended variations due to manufacturing tolerances and narrow-range wavelength tunability. Each DFB-DML of DFB-DMLs 210 may be individually tuned to a target grid wavelength by adjusting a bias current and a temperature of the TEC surface, on which the PIC 200 may be mounted.

If the range of each DFB-DML tunability is Δλ_{DFB}, the grating pitch shift of

$$ΔΛ \leq \frac{m {Δλ}_{DFB}}{2 {n}_{DFB} ( {λ}_{DFB} )} [ 1 - \frac{dln ( {n}_{DFB} )}{dln ( {λ}_{DFB} )} ] \qquad Eq . 4$$

allows for the overlap of the DFB-DML tunable ranges between the lasers with adjacent wavelengths, such that, in use, a much wider continuous tunability range MΔλ_{DFB} is feasible, where M is the laser count in the tunable laser array (TLA).

Depending on the tunability range of each DFB-DML, a lower number of DFB-DMLs 210 may be present than the number of channels of a target grid while still allowing for each channel of the target grid to be tuned to. That is, if a wavelength tuning range of each DFB-DML is greater than the spacing in the wavelength domain of the target grid, fewer DFB-DMLs than the number of channels may be needed to emit at any of the target grid's channels.

To achieve a wide-range tunability by using narrowly-tuned DFB-DMLs, at any given time only one DFB-DML of DFB-DMLs 210 should be active such that output signal 240 includes light output from a single DFB-DML of DFB-DMLs 210. Therefore, EDG-WDM 220 must couple the light output of a single DFB-DML 210 to be output as output signal 240. Since EDG-WDM 220 is tuned to have a passband center wavelength match a target wavelength (e.g., corresponding to a target grid frequency), which is the same as the target frequency that the DFB-DMLs output is tuned to, the coupling loss may be minimized.

As in relation to PIC 100, the number of DFB-DMLs 210 may vary by embodiment on PIC 200. Since the continuous tunability range of a DFB-DML varies by temperature, if a DFB-DML can be exposed to a greater temperature range, the number of DFB-DMLs needed to be able to tune over an wavelength range of channels may be decreased. However, in some embodiments, a higher count of DFB-DMLs may be desired to decrease the temperature range to which such DFB-DMLs need to be exposed to achieve the wavelength range of desired channels.

The DFB wavelength is defined by the grating pitch λ but can be changed, within its tunability range, by adjusting the TEC surface temperature (not illustrated in FIG. 2 and which may cool PIC 200) and the bias current applied to the individual DFB-DML, represented by bias currents 211, as indicated in Equation 5:

$${δλ}_{DFB} = \frac{\partial {λ}_{DFB}}{\partial {T}_{TEC}} δ {T}_{TEC} + \frac{\partial {λ}_{DFB}}{\partial {I}_{TEC}} δ {I}_{DFB} \qquad Eq . 5$$

In Equation 5, δT_{TEC} represents the TEC surface temperature variance, δI_{DFB} represents the DFB-DML bias current variance, while ∂λ_{DFB}/∂T_{TEC} and ∂λ_{DFB}/∂I_{DFB} are the tuning rates of the DFB laser emission wavelength associated with the TEC surface temperature and DFB-DML bias current variations, respectively, each of which remaining nearly constant within their respective ranges of variance (hence linear approximation of Eq. 5).

Variances of the TEC surface temperature δT_{TEC} and the bias current δI_{DFB} also affect the output optical power of the laser diode P_{DFB}, which could be expressed in a way similar to Equation 5:

$$δ {P}_{DFB} = \frac{\partial {P}_{DFB}}{\partial {T}_{TEC}} δ {T}_{TEC} + \frac{\partial {P}_{DFB}}{\partial {I}_{DFB}} δ {I}_{DFB} \qquad Eq . 6$$

In Equation 6, ∂P_{DFB}/∂T_{TEC} and ∂P_{DFB}/∂I_{DFB} are the rates of change in the output power with the variations of the TEC temperature and bias current, respectively. Linear approximation of Equation 6, is, strictly speaking, limited to a certain ranges the δT_{TEC} and δI_{DFB} variances, but to those skilled in the art it should be clear that a general case of nonlinear dependence P_{DFB} (T_{TEC}, I_{DFB}) does not change the operating principle of the invention.

In a practical example of the target optical frequency grid that consists of 32 100-GHz spaced ITU-grid channels in communication C-band, centered at about 1545 nm, and thermal tuning with a typical DFB wavelength tuning rate of dλ/dT≈0.09 nm/° C., δλ≈0.8 nm, the temperature tuning range that corresponds to the spacing between two adjacent channels is δT=(dλ/dT)⁻¹δλ≈9° C. This means that for M=16, 10, and 8, the temperature operation range should be ΔT≥9° C., 18° C., and 27° C., respectively.

There can be a trade-off between the continuous tunability range of the individual laser diodes and the laser count in the array. The former is limited by the laser gain variation with the temperature, on one hand, and the power consumption of the TEC, on another. The TEC power consumption can be significantly affected by the ambient temperature range. The wider this range the more power required for the same temperature tunability range. In a case of the industrial ambient temperature range, −40° C. to +85° C., temperature tunability range ΔT≥27° C. may be difficult to achieve and hence a relatively high laser count M≥10 may be required.

EDG-WDM 220 may have input channel passbands defined by the wavelength plan it addresses, including the wavelength channel count and spacing, as well as the overall EDG-WDM design. The insertion loss of the EDG-WDM, defined as the output waveguide coupled optical power relative to the input waveguide coupled optical power, depends on the passband shape and the input channel wavelength position relative to the passband. The minimal insertion loss usually is achieved at the passband center wavelength of a bell-like, e.g. Gaussian, passband. Therefore, it is desirable to have the wavelength of light launched into the EDG-WDM input channel matching the passband center wavelength of the EDG-WDM. If the input wavelength is fixed, e.g. is tuned to a certain plan wavelength, the only option to match the EDG-WDM passband center wavelength is to tune it to the input wavelength.

The passband center wavelengths (λ_{WDM}) of the EDG-WDM 220 are defined at least in part by the design parameters of the EDG-WDM, such as grating period, diffraction order, and position of the input and output waveguides on the Rowland circle. The passband center wavelengths also depend on the effective index in the slab waveguide, an integral part of the EDG-WDM that forms the diffractive image of the input waveguides into the output waveguide. The latter is affected by the temperature in the slab waveguide area, which, in turn, can be at least in part controlled by the TEC surface temperature (T_{TEC}) and the electrical current (I_{WDM}) that feeds the thermo-electrical heater in the slab waveguide area. In the linear approximation that works well over practical ranges of the TEC temperature and heater's current variances, δT_{TEC} and δI_{WDM}, respectively, variation of the center wavelength δλ_{WDM} is related to these in accordance with Equation 7:

$${δλ}_{WDM} = \frac{\partial {λ}_{WDM}}{\partial {T}_{TEC}} δ {T}_{TEC} + \frac{\partial {λ}_{WDM}}{\partial {I}_{WDM}} δ {I}_{WDM} \qquad Eq . 7$$

Both the TEC temperature and the heater current variances can result in a change of the EDG-WDM slab waveguide area temperature, which, in turn generates the passband center wavelength drift at a rate, similar to that of the temperature drift of the DFB laser emission wavelength. Consequently, same estimates for the temperature range as those above in a case of the DFB laser emission wavelength can hold and, for example, temperature tuning of the EDG-WDM passband center wavelength over two 100-GHz spacings would require 18° C. heating in the slab waveguide area.

Thermal isolation 250 represents that EDG-WDM 220 and heater 130 are at least partially thermally isolated from DFB-DMLs 210. Partial thermal isolation 250 can be realized by virtue of the poor thermal conductivity of InP and related III-V semiconductor materials.

As Equations 5-7 indicate, there are three key performance parameters of the PIC: the DFB-DML emission wavelength, the DFB-DML output power, and the EDG-WDM passband center wavelength, which are controlled by three external parameters: the TEC temperature, the DFB-DML bias current, and the EDG-WDM heater current. In use, the performance parameters of PIC 200 can be independently tuned to their respective targets, thereby allowing for an optimal performance of the PIC. In a 100-GHz (approximately 0.8-nm) spacing example, if the PIC 200 has ten DFB-DMLs 210, then the laser emission wavelength targets may be set at every fourth channel wavelengths, i.e., channels in accordance with Equation 8:

i=2+3k, k=0,1, . . . 10 Eq. 8

Thermal isolation 250 represents that EDG-WDM 220 and heater 130 are at least partially thermally isolated from DFB-DMLs 210. Thermal isolation 250 may be realized by virtue of the poor thermal conductivity of the substrate (e.g., InP). Additionally or alternatively, techniques such as deep trench etching may be performed in the epitaxial deposits on the substrate, which can provide further thermally insulation of EDG-WDM 220 from DFB-DMLs 210.

As discussed in relation to PIC 100, PIC 200 may be in physical contact with a thermally-conductive substrate, such as a thermally conductive piece of metal, that transfers heat to a TEC that is separate from PIC 200. The TEC may cool a surface of PIC 200 to roughly a constant temperature. For PIC 200, in order to adjust the wavelength of light output as output signal 240, three conditions can be controlled, a temperature of PIC 200 (which can be realized by controlling the temperature of the TEC), a bias current of the analog signal being supplied to the DFB-DML of DFB-DMLs 210 in use, and the temperature of an image defining region of EDG-WDM 220 using heater 130. As previously detailed, in addition to the bias current affecting the temperature of a DFB-DML, the bias current affects the optical power output by the DFB-DML. In such instances, the temperature of PIC 200 controlled by the TEC and the WDM temperature controlled by heater 130 may remain sufficient to allow for independent adjustment of λ_{WDM} and λ_{DFB}.

In a 32-channel, 100-GHz spacing example, if PIC 200 has ten DFB-DMLs 210, then the reference point on the plane (T_{TEC}, I_{WDM}) should be set such that the laser wavelengths coincide with the every fourth channel wavelengths, i.e., channels in accordance with Equation 8:

i=2+3k, k=0,1, . . . 10 Eq. 8

Then with the DFB-DML tunability range Δλ_{DFB}≥1.6 nm, the k-th DFB-DML will cover (1+3k)-th, (2+3k)-th, and (3+3k)-th wavelength plan channels, overall amounting to 33 100-GHz spaced channels using 10 DFB-DMLs.

In the same example, EDG-WDM 220 has 10 input channels and one output channel, that is, it is a 10:1 WDM. The passband center wavelength targets may be set as the DFB-DML wavelengths above, i.e. on i=2+3k, k=0, 1, . . . 10 plan channels. Then, with the WDM tunability range ≥1.6 nm, the k-th WDM channels covers (1+3k)-th, (2+3k)-th, and (3+3k)-th plan channels, k=0, 1, . . . 10, overall amounting to 33 100-GHz spaced channels.

Once both the DFB-DML emission wavelength and the EDG-WDM passband center wavelength are set to the same target wavelength, e.g. a certain plan wavelength, they match each other, and hence the EDG-WDM insertion loss reaches its minimum while the laser power transmitted to its output port reaches its maximum.

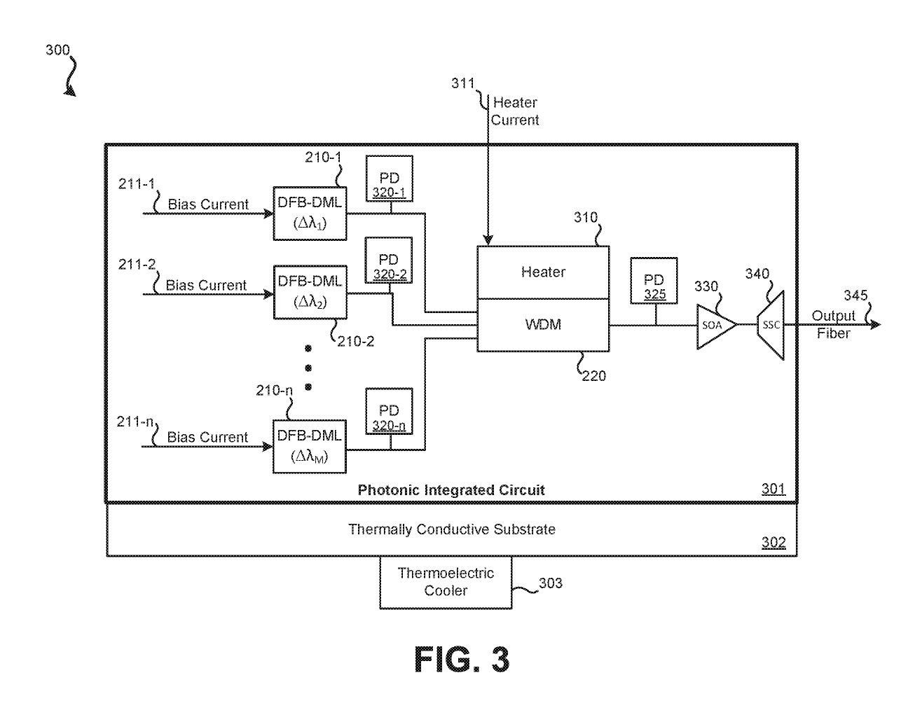

FIG. 3 illustrates an embodiment of a system 300 that includes a tunable laser array PIC 301. PIC 301 may represent a more detailed embodiment of PICs 100 and 200 of FIGS. 1 and 2, respectively. System 300 may include PIC 301, thermally conductive substrate 302, and TEC 303. TEC 303 may be used to control temperature of a surface of PIC 301 by absorbing heat transferred from PIC 301 via thermally conductive substrate 302, which may be in thermal contact with PIC 301. Thermally conductive substrate 302 may be made of a thermally conductive material, such as aluminum nitride.

PIC 301 may additionally include photodiodes (PDs) 320, which may each be part of the laser's optical power monitor circuit. PDs 320-1, 320-2, and 320-n receive a small percentage of the output light from each respective DFB-DML of DFB-DMLs 210. PDs 320 may receive light from a tap of the waveguide connected with the output of DFB-DMLs 210 and EDG-WDM 220. PDs 320 are used to monitor the optical power at the output of the DFB-DMLs 210. It should be understood that only one DFB-DML is operational at any time and a single PD of PDs 320 may receive light from a single DFB-DML of DFB-DMLs 210 to which it is coupled. Therefore, if, for example, ten DFB-DMLs 210 are present in an embodiment, ten PDs 320 may be present on PIC 301, with a PD associated with each of the ten DFB-DMLs. The power measured by a PD of PDs 320 may be used as a feedback loop to adjust the power (by adjusting the bias current) of the associated DFB-DML of DFB-DMLs 210.

PD 325 may be coupled to the passive waveguide at the EDG-WDM output channel to tap off a small fraction of the this waveguide power and detect it for the purpose of the power monitoring. Since such an optical power in the output waveguide of the EDG-WDM depends on the working laser emission wavelength relative to the multiplexer's passband center wavelength, associated with the multiplexer's input coupled to the working laser, the power monitor may be used as the wavelength mismatch monitor. This measurement may be used as feedback to align a passband center wavelength of EDG-WDM 220 with the wavelength of the light output by the active DFB-DML of DFB-DMLs 210. As the heater 310 current changes the temperature—and hence the effective refractive index of the slab waveguide—in the image defining region of EDG-WDM 220, when the output power measured by PD 325 is at a maximum, a passband center wavelength of EDG-WDM 220 may be aligned with the output wavelength of the active DFB-DML of DFB-DMLs 210. Since the latter is already tuned to correspond to a target optical frequency of a frequency grid, both the laser emission wavelength and multiplexer passband center wavelength are aligned to correspond to the target optical frequency.

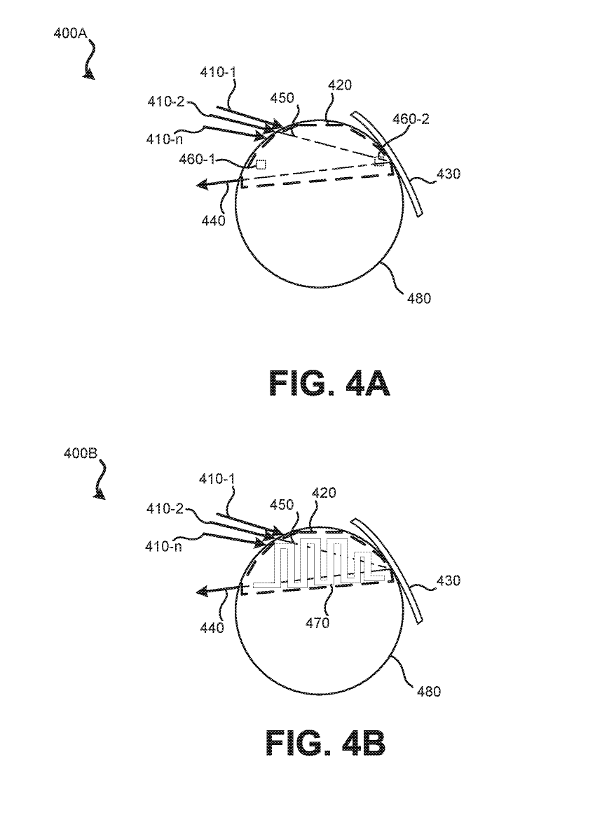

Heater 310 may receive heater current 311 from an electronic controller residing off of PIC 301. The electronic controller may receive power measurements from PD 325 and may determine an amount of current 311 to apply to heater 310. Heater 310 may transform this current into heat output to raise the temperature of an image forming area of EDG-WDM 220. Therefore, while thermoelectric cooler 303 may cool PIC 301, heater 310 may locally raise the temperature of at least a portion of EDG-WDM 220. Additional detail regarding possible embodiments of heaters 130 and 310 are provided in relation to FIGS. 4A and 4B.

Coupled with the output of EDG-WDM 220 may be a booster semiconductor optical amplifier (SOA) 330. SOA 330 may amplify the output of EDG-WDM 220 to raise the optical power level of the output signal and thereby compensate for on-chip insertion loss. The output of SOA 330 may be terminated with a spot-size converter (SSC) 340. SSC 340 may at least partially compensate for a mode mismatch between the output waveguide of the EDG-WDM and cleaved standard single-mode fiber (SSMF), thereby enabling for a more efficient coupling of the waveguide on PIC 301 with such a fiber. SSC 340 and SOA 330 may be formed as part of the monolithic PIC 301. Remaining portions of PIC 301, including DFB-DMLs 210, EDG-WDM 220, and thermal isolation 250 function as detailed in relation to PIC 200 of FIG. 2.

FIGS. 4A and 4B illustrate embodiments of heaters incorporated as part of a tunable laser array PIC. The heater embodiments of FIGS. 4A and 4B may function as heaters 130 and 310. EDG-WDM 400A is illustrated in Rowland configuration (with Rowland circle 480 visible). EDG-WDM 400A has a slab waveguide region in which light received from DFB-DMLs in waveguide 410 (410-1, 410-2, 410-n) is free to propagate in two dimensions. While EDG-WDM 400A is illustrated with three waveguides 410 feeding light from DFB-DMLs, it should be understood that the number waveguides feeding light into the image defining slab waveguide region of EDG-WDM 400A is dependent on the number of DFB-DMLs of the PIC. As such, in a RoF application in which 32 or 64 channels in a frequency plan are present, typically between 5 and 20 inputs to EDG-WDM 400A may be present (one input from each DFB-DML), however other numbers of inputs, both greater and fewer, are possible. Light emitted from each of waveguides 410 into the slab waveguide may propagate through image defining region 420 of the slab waveguide. This light may be diffracted by Echelle grating 430 to output waveguide 440, if certain phase conditions for multi-beam interference are met. These conditions are defined by the EDG layout in Rowland configuration, its period, diffraction order, wavelength, and the effective index in the slab waveguide area at that wavelength, affected by heater. Path 450 illustrates an exemplary path of light passing from waveguide 410-2 to Echelle grating 430 and diffracted to output waveguide 440 through image defining region 420 of the slab waveguide of EDG-WDM 400A.

Situated on top of the slab waveguide may be a conductive layer. The conductive layer may have been formed as part of an epitaxial structure to serve, at least in part, as the upper cladding of the slab waveguide. Electrical contacts 460 (460-1, 460-2) may be formed to a conductive layer, in a configuration enabling for an electrical current flowing in the part of the conductive layer that belongs to the image defining area of the EDG-WDM. Once electrical bias applied to electrical contacts 460, the current flowing through the conductive layer causes this layer to heat. Heat can propagates down into the other slab waveguide layers, increasing the effective index in the image defining region 420, which alters the passband center wavelengths of EDG-WDM 400A.

In EDG-WDM 400B of FIG. 4B, a dielectric, such as silicon nitride, is deposited atop the slab waveguide area in the EDG-WDM. This dielectric may be thick enough for the slab waveguide's mode optical field decaying beyond significance at its upper surface while being thin enough for its thermal conductivity to keep the lower surface at about the same temperature as the upper surface. Atop the dielectric, one or more metallic resistive heaters 470 may be deposited. In the illustrated embodiment of EDG-WDM 400B, metallic resistive heater 470 is deposited on the dielectric layer such that heat generated by resistive heater 470 is transferred down to the slab waveguide of EDG-WDM 400B, in its image defining region 420. An electrical current supplied to the metallic resistive heater 470 may create heat in the dielectric layer, which transfers down to the image defining area of the slab waveguide and thereby increases the effective index of the slab waveguide in this area, resulting in the red shift of the EDG-WDM 400B passband center wavelengths. It should be understood that the dielectric layer and the layout of the one or more metallic resistive heaters 470 deposited upon it may vary by embodiment.

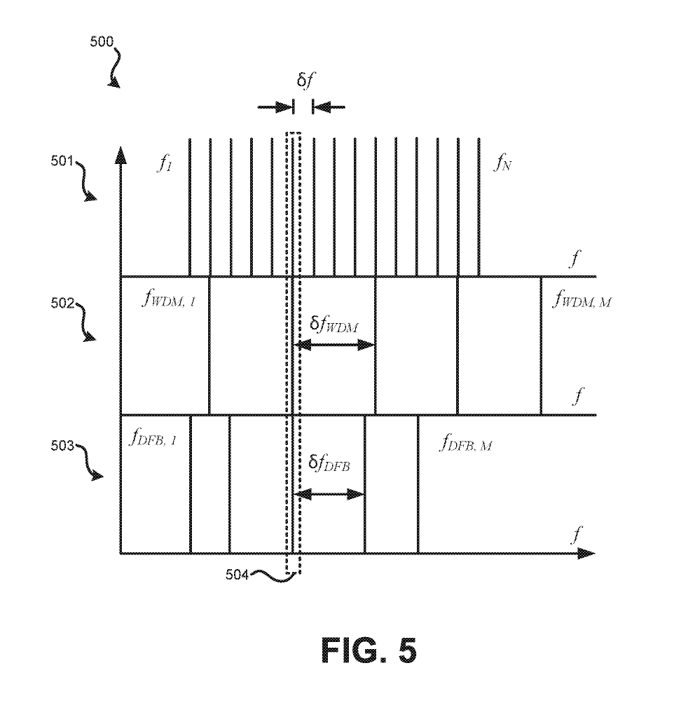

FIG. 5 illustrates an embodiment 500 of a dense wavelength-division multiplexing (DWDM) frequency grid 501, WDM passband center frequencies 502, and DFB-DML array optical frequencies 503. As described in relation to Equation 2, the N channels of a frequency grid may be equally spaced by δf. The passband center optical frequencies can be tuned by adjusting temperature of in the image defining slab waveguide area of the EDG-WDM, which affects the effective refractive index of the slab waveguide therein. For WDM passband center optical frequencies 502, f_{WDM} represents the passband center optical frequencies of an WDM, such as that used in PICs 100, 200, and 301. DFB-DMLs array optical frequencies f_{DFB} 503 represent the optical frequencies of light emitted by individual DFB-DMLs present on a PIC, such as PICs 100, 200, and 301. These optical frequencies can be tuned by adjusting the TEC temperature and each individual DFB-DML bias current. Both the WDM passband center and the DFB laser emit optical frequencies are affected by manufacturing tolerances and may not be evenly spaced, which also can be compensated by their respective tunabilities.

In order to output light at a particular grid frequency of dense wavelength-division multiplexing (DWDM) frequency grid 501, a DFB-DML which has the particular frequency within its tunability range may be tuned to the particular frequency by adjusting temperature of the DFB-DML (e.g., by controlling a bias current of the DFB-DML and the TEC temperature). A passband center frequency of WDM passband center optical frequencies 502 may then be adjusted to maximize power output by centering a passband center frequency on the particular frequency, as output by the DFB-DML or the WDM could be tuned to the same frequency selected from the frequency grid. An example of this arrangement is shown by the alignment of optical frequencies 504, which illustrates the output frequency of a DFB-DML and the passband center frequency of a WDM being matched to a desired frequency of a frequency grid.

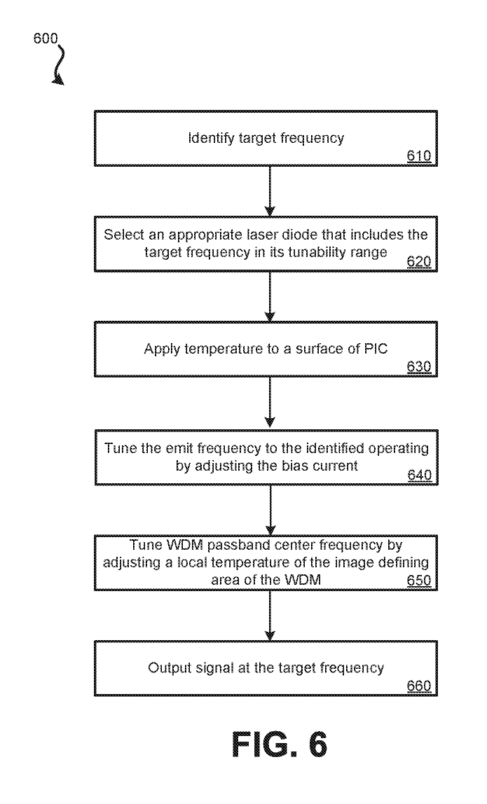

The devices and systems of FIGS. 1-4 may be used to perform various methods in accordance with the present disclosure. FIG. 6 illustrates an embodiment of a method 600 for emitting light at a selected wavelength. Method 600 may, for example, be used to emit light at a particular wavelength of the ITU grid that defines standard channels for optical communication, such as for RoF applications. In other embodiments, method 600 may be used for emitting at a particular wavelength that does not correspond to a standardized frequency grid. Method 600 may be performed using PIC 100, PIC 200, or PIC 301 (possibly as part of system 300).

At block 610, a desired target wavelength to be output by the PIC may be identified. This wavelength may correspond to a frequency present on a predefined frequency grid, such as the ITU grid for an RoF application or various other applications. In other situations, the wavelength may be selected for a specialized use that does not necessarily conform to any established frequency grid.

At block 620, a laser diode (e.g., DFB-DML) of the PIC may be selected to output light at the identified target wavelength. The laser diode selected at block 620 can be a laser diode that, within its tunability range, can emit at the identified wavelength. Each laser diode of the multiple laser diodes present on the PIC may have varying grating pitches, thus causing each laser diode to have a different tunable wavelength range. Only the laser diode selected at block 620 may be supplied with a signal having a bias current such that only the selected laser diode is actively outputting light from among the laser diodes of the PIC. Selection of the laser diode at block 620 may be performed by a separate controller or processor that is in communication with the PIC. Selection of the laser diode may be performed based on input provided to the PIC.

At block 630, the temperature of a surface of the PIC may be controlled. Heating or cooling may be applied to a back of the PIC to control the temperature of the substrate of the PIC. A TEC may be used to set and control this temperature. The temperature of the TEC may be selected based on the desired range of tunability of individual laser diodes, as detailed in relation to Equation 5.

At block 640, the wavelength of light emitted by the selected laser diode may be adjusted to match the target wavelength by adjusting a bias current. By adjusting the bias current and thus the temperature of the laser diode, the wavelength emitted within the laser diode's tunable range may be varied, along with other operating characteristics including the output optical power.

At block 650, a local temperature of the WDM may be adjusted to adjust a passband center wavelength of the WDM to match the target wavelength. The local temperature may be controlled by applying heat to the WDM, more specifically to the image forming area of the WDM as explained above. The temperature may be adjusted using a heater controlled by an electronic controller distinct from the PIC. The heater may be as detailed in relation to FIGS. 4A and 4B. The local temperature of the image defining region of the WDM's slab waveguide region may be controlled. This adjustment in temperature may cause a passband center wavelength of the multiplexer to change. In some embodiments, the temperature of the WDM is tuned until a center passband wavelength of the WDM matches the identified target wavelength of block 610. In some embodiments, this temperature can be adjusted until a maximum amount of optical power is measured as being output by the WDM, such as using a power meter (which may have a photodiode, such as PD 325 incorporated as part of the PIC).

At block 660, the light may be output by the PIC at the identified target wavelength. This wavelength may correspond to a particular frequency on a frequency grid, such as the ITU frequency grid. The light may be converted to a format appropriate for transmission through optical cable, such as by using a SSC and amplified using an amplifier. The output light may be used for a RoF application. For analog applications such as ROF, the amplitude of a data signal supplied to the DFB-DML is small compared to the current bias supplied to the DFB-DML and hence all that depends on the current, including wavelength, is controllable via the bias current, leaving the signal intact.

The methods, systems, and devices discussed above are examples. Various configurations may omit, substitute, or add various procedures or components as appropriate. For instance, in alternative configurations, the methods may be performed in an order different from that described, and/or various stages may be added, omitted, and/or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations will provide those skilled in the art with an enabling description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of steps may be undertaken before, during, or after the above elements are considered.

1. A photonic integrated circuit (PIC) acting as a tunable laser array (TLA) tunable across a first range of wavelengths, comprising:
a substrate;
an epitaxial structure upon the substrate;
a plurality of distributed feedback (DFB) lasers in the epitaxial structure, wherein a wavelength of each DFB laser of the plurality of DFB lasers is tunable, within a second tuning range that is a subset of the first range, based at least in part on a temperature of the PIC, whereby the DFB laser wavelength may be tuned to a desired wavelength within the first range, the plurality of DFB lasers being configured such that at any time, only one of the plurality of DFB lasers operates, by emitting at an output thereof, at a wavelength within the first range;
a wavelength-division multiplexer (WDM) in the epitaxial structure, wherein the WDM comprises a plurality of optical inputs each coupled to the DFB laser outputs to receive light from each DFB laser of the plurality of DFB lasers when emitted, wherein passband center wavelengths of the WDM are continuously tunable based at least in part on a temperature of the WDM; and
a heater disposed and configured to selectively heat the WDM, whereby the passband center wavelengths of the WDM may be tuned to the desired wavelength.

2. The PIC of claim 1, wherein the plurality of DFB lasers and the WDM are disposed and configured such that laser emission wavelengths and the WDM passband center wavelengths are controllable independently of one another.

3. The PIC of claim 1, wherein the WDM comprises an Echelle grating (EG) having a slab waveguide region.

4. The PIC of claim 1, wherein each DFB laser of the plurality of DFB lasers is a distributed feedback, directly modulated laser (DFB-DML) of a plurality of DFB-DMLs.

5. The PIC of claim 4, wherein the WDM comprises an Echelle grating (EG) having a slab waveguide region.

6. The PIC of claim 5, wherein the heater comprises a conductive layer adjacent and thermally coupled to the slab waveguide region of the EG.

7. The PIC of claim 5, further comprising a dielectric layer on the epitaxial structure, wherein the heater comprises a metal resistive heater disposed on the dielectric layer adjacent and thermally coupled to the slab waveguide region of the EG.

8. The PIC of claim 4, wherein each DFB-DML of the plurality of DFB-DMLs has a distributed feedback (DFB) grating having a pitch, wherein the DFB grating pitches differ from one another, whereby each DFB-DML of the plurality of DFB-DMLs has a different tuning range.

9. The PIC of claim 4, wherein a temperature of each individual DFB-DML of the plurality of DFB-DMLs is at least partially controlled based on a bias current supplied to the individual DFB-DML.

10. The PIC of claim 1, further comprising a semiconductor optical amplifier (SOA) in the epitaxial structure, wherein the SOA receives and amplifies output light from the WDM.

11. The PIC of claim 1, wherein the plurality of DFB lasers comprises at least ten DFB lasers.

12. The PIC of claim 1, further comprising a plurality of photodiodes on the substrate, wherein:
each photodiode of the plurality of photodiodes is optically coupled to a different DFB laser of the plurality of DFB lasers, and
a photodiode of the plurality of photodiodes is optically coupled to the WDM.

13. The PIC of claim 1, wherein the substrate is an InP substrate.

14. The PIC of claim 1, wherein the substrate is configured to be cooled by a thermoelectric cooler.

15. A tunable light source, tunable across a first range of wavelengths, comprising:
a photonic integrated circuit (PIC), comprising:
a substrate;
an epitaxial structure on the substrate;
a plurality of distributed feedback (DFB) lasers in the epitaxial structure, wherein a wavelength of each DFB laser is tunable within a second tuning range that is a subset of the first range, based at least in part on a temperature of the tunable light source, whereby the DFB laser wavelength may be tuned to a desired wavelength within the first range, the plurality of DFB lasers being configured such that at any time, only one of the plurality of DFB lasers operates, by emitting at an output thereof, at a wavelength within the first range;
a wavelength-division multiplexer (WDM) in the epitaxial structure, wherein the WDM comprises a plurality of optical inputs each coupled to the DFB laser outputs to receive light from each DFB laser of the plurality of DFB lasers when emitted, wherein passband center wavelengths of the WDM are continuously tunable based at least in part on a temperature of the WDM; and
a heater disposed and configured to selectively heat the WDM, whereby the passband center wavelengths of the WDM may be tuned to the desired wavelength;
a thermally-conductive substrate in thermal contact with the PIC; and
a thermoelectric cooler in thermal contact with the thermally-conductive substrate.

16. The tunable light source of claim 15, wherein:
the WDM comprises an Echelle grating (EG) having a slab waveguide region; and
the heater comprises a conductive layer adjacent the slab waveguide region of the EG.

17. The tunable light source of claim 15, wherein the WDM comprises an Echelle grating (EG) having a slab waveguide region, the tunable light source further comprising a dielectric layer on the epitaxial structure, wherein the heater comprises a metal resistive heater disposed on the dielectric layer adjacent the slab waveguide region of the EG.

18. The tunable light source of claim 16, wherein the plurality of laser diodes are a plurality of distributed feedback directly-modulated lasers (DFB-DMLs).

19. The tunable light source of claim 18, further comprising a semiconductor optical amplifier (SOA) defined within the epitaxial structure that receives and amplifies light output fom the WDM.

20. A method for using a tunable laser array (TLA) photonic integrated circuit (PIC) tunable across a first range of wavelengths comprising a substrate and an epitaxial structure on the substrate, the epitaxial structure comprising a plurality of distributed feedback (DFB) lasers configured such that at any time, only one of the plurality of DFB lasers operates, by emitting at an output thereof, at a wavelength within the first range, and a wavelength-division multiplexer (WDM) comprising a plurality of optical inputs each optically coupled to receive light from the outputs of the plurality of DFB lasers when emitted, using optical waveguides, the method comprising:
controlling a temperature of the PIC using a thermoelectric cooler;
adjusting a wavelength of a first DFB laser of the plurality of DFB lasers within a second tuning range that is a subset of the first range, to match a desired wavelength by altering a bias current supplied to the first laser diode; and
selectively applying heat to the WDM to adjust a passband center wavelength of the WDM to match the desired wavelength.

21. The method of claim 20, wherein the WDM comprises an Echelle grating comprising a slab waveguide, and wherein the heat is selectively applied to the slab waveguide.

22. The method of claim 20, further comprising selecting the first DFB laser such that the desired wavelength is within a tunable wavelength range of the first DFB laser.
